(19) United States
(12) Patent Application Publication
(10) Pub. No.: US 2007/0170465 A1
(43) Pub. Date: Jul. 26, 2007

(54) Level shifter for flat panel display device

(76) Inventors: Oh Kyong Kwon, Seoul (KR); Byong Deok Choi, Seoul (KR)

Correspondence Address: CHRISTIE, PARKER & HALE, LLP, PO BOX 7068, PASADENA, CA, 91109-7068, US

(21) Appl. No.: 11/601,372

(22) Filed: Nov. 17, 2006

(30) Foreign Application Priority Data
Jan. 20, 2006 (KR) 10-2006-0006252
Feb. 9, 2006 (KR) 10-2006-0012561

(51) Int. Cl. H01L 31/00

(52) U.S. Cl. 257/197

(57) ABSTRACT

A level shifter for a flat panel display device is provided. A first transistor has a first transistor source, a first transistor gate, and a first transistor drain. The first transistor source is connected to a first power supply and the first transistor gate and the first transistor drain are connected together. A capacitor is connected between an input voltage terminal and a first node with the first node connected to the first transistor gate and the first transistor drain. A second transistor is connected with the first node to reset the capacitor. A third transistor has a third transistor gate, a third transistor source, and a third transistor drain. The third transistor gate is connected to the first node, and the third transistor source and the third transistor drain are connected between a second power supply and an output voltage terminal. A fourth transistor has a fourth transistor gate, a fourth transistor source, and a fourth transistor drain. The fourth transistor gate is connected to the input voltage terminal, and the fourth transistor source and the fourth transistor drain are connected between a ground voltage terminal and the output voltage terminal.

### CROSS-REFERENCE TO RELATED APPLICATIONS

This application claims priority to and the benefit of Korean Patent Application Nos. 2006-006252, filed on Jan. 20, 2006 and 2006-12561, filed on Feb. 9, 2006 in the Korean Intellectual Property Office, the entire content of which is incorporated herein by reference.

### BACKGROUND

1. Field of the Invention

The present invention relates to a level shifter, and in particular to a level shifter for a flat panel display device with decreased power consumption and improved propagation delay.

2. Discussion of Related Art

Flat panel display devices include a liquid crystal display, a field emission display, a plasma display panel, and a light emitting display. Generally, flat panel display devices are realized in an active matrix having a pixel array arranged in a matrix that cross-links parts between data lines and scan lines.

The scan lines constitute horizontal lines (row lines) of the matrix pixel array. The horizontal lines (row lines) sequentially supply a predetermined signal, namely a scan signal to each pixel of the pixel array using a scan drive circuit.

The data lines constitute vertical lines (column lines) of the matrix pixel array. The vertical lines (column lines) sequentially supply a predetermined data signal, synchronized with the scan signal, to each pixel of the pixel array using a data drive circuit.

The scan drive circuit consists of a plurality of gate shift registers in which outputs are individually connected to a plurality of level shifters. The gate shift registers shift an input gate start pulse (GSP) to supply sequentially the shift pulse to the level shifters. The level shifters enhance a swing voltage for the shift pulse from the gate shift registers to supply a scan signal to the scan lines.

The data drive circuit consists of a plurality of data shift registers and sampling switches in which outputs are individually connected to a plurality of level shifters. The data shift registers shift an input data start pulse (DSP) to supply sequentially a shift signal to the level shifters. The level shifters are individually connected between the data shift registers and the sampling switches to enhance their swing voltage for the shift pulse from the data shift registers, thereby supplying a sampling signal to the sampling switches. The sampling switches sequentially sample the video signal. The sampling switch outputs are individually connected to the data lines, thereby supplying the sampled video signal to the data lines.

Level shifters provided in a flat panel display device function to enhance the swing width of an input pulse. An enhanced swing width is needed because a pulse having a swing voltage greater than a certain width is requisite to drive thin film transistors of each pixel provided in the pixel array of the flat panel display device.

FIG. 1A and FIG. 1B show circuit diagrams of a conventional level shifter. FIG. 1A shows a configuration of a level up shifter and FIG. 1B shows a configuration of a level down shifter.

In FIG. 1A, VDDH is the supply voltage of the level up shifter. In FIG. 1B, VDDL and VSS are the supply voltages of the level down shifter. IN is the input voltage of the level up/down shifters and OUT is the output voltage.

Referring to FIG. 1A, the conventional level up shifter consists of first and second N-channel transistors NM1, NM2 for receiving an input voltage IN and a reversed input voltage INb and a latch circuit for leveling up the input voltage. The latch circuit consists of first and second P-channel transistors PM1, PM2.

The gates of NM1 and NM2 are connected to an input voltage IN and a reversed input voltage INb, respectively. The sources of NM1 and NM2 are connected to a ground voltage GND. And the drains of NM1 and NM2 are connected to first and second nodes A, B, respectively, thereby connecting NM1 and NM2 to the latch circuit. The second node B is the output voltage OUT.

With respect to the latch circuit, the gates and drains of PM1 and PM2 are cross-linked to be connected between the first and second nodes, respectively, and the sources are connected to a supply voltage VDDH of the level up shifter.

With respect to the conventional level up shifter, if VDDH is set to 10 V and the input voltage IN ranges from 0 V to 5 V, the output voltage OUT will range from 0 V to 10 V. INb is at a low level, namely 0 V, when IN is at a high level, namely 5 V. INb is at a high level (5 V) when IN is at a low level (0 V).

If IN is 5 V, then NM1 to which the IN is applied is turned on, and NM2 to which the INb is applied is turned off. Accordingly, PM2 is turned on upon NM1 being turned on, and an output voltage OUT is leveled up to 10 V by the supply voltage VDDH.

If IN is 0 V, then NM2 to which the INb is applied is turned on, and NM1 to which the IN is applied is turned off, therefore the output voltage OUT becomes 0 V.

The level down shifter as shown in FIG. 1B operates by the same principle as described in the level up shifter.

The operation of the level up shifter follows. If the input voltage IN makes a transition from a low level (0 V) to a high level (5 V), then NM1 is turned on and NM2 is turned off. As NM1 is turned on, the first node A returns to a low level, and then PM2 is turned on. Accordingly, the second node B returns to a high level, and then PM1 is turned off. As a result, the voltage level of the second node B will be identical to the level-up voltage, namely VDDH by the PM2, and this voltage (10 V) is supplied to the output voltage OUT.

Meanwhile, if the input voltage IN makes a transition from a high level (5 V) to a low level (0 V), then NM1 is turned off, and NM2 is turned on. As NM2 is turned on, the second node B returns to a low level, and then PM1 is turned on. Accordingly, the first node A returns to a high level, and then PM2 is turned off. As a result, the voltage level of the second node B returns to a low level (0 V) because NM2 is turned on, and this voltage (0 V) is supplied to the output voltage OUT.

However, because PM2 remains turned on and NM2 makes a transition from a turned-off state to a turned-on state at a point of time in which the input voltage IN makes a transition from a high level to a low level, both PM2 and NM2 are maintained turned on, and therefore a current passage is formed between PM2 and NM2 during the period. In addition, upon a transition from low to high in the input voltage, both PM1 and NM1 are maintained turned on at a point of time in which the input voltage IN makes a transition from a low level to a high level, and therefore a current passage is formed between PM1 and NM1. A short circuit current generated at these times is a disadvantage of the conventional level shifter because it increases the power consumption of the circuit.

Another disadvantage of the conventional level shifters is that its rising and falling propagation delay differs. If the input voltage makes a transition from a low level to a high level, then two phases are required for generating an output voltage. If the input voltage makes a transition from a high level to a low level, then only one phase is required for generating an output voltage. Thus, the conventional level shifter has different rising and falling propagation delays due to the different operational phases upon generating the output voltage.

A further disadvantage is that the conventional level shifter has a characteristic that its circuit operates only if the transistors NM1 and NM2 to which the input voltage is applied has greater current driving capacity than those of the cross coupled transistors PM1 and PM2, and therefore it has a disadvantage that NM1 and NM2 must have a sufficiently large channel width.

As described above, if W (Width)/L (Length), namely the size of the transistors NM1 or NM2 to which the input voltage is applied increases, then a capacitance value corresponding to the input signal is increased, and therefore its slope is reduced when the input voltage makes a transition from a low level (0 V) to a high level (5 V), or from a high level (5 V) to a low level (0 V). Because PM1 and NM1 or PM2 and NM2 may be turned on at the same time, short circuit current is generated until the structurally symmetrical and opposite cross coupled transistor is turned on. The reduction of the slope increases the period in which the conventional level shifter is short circuited, which further increases the power consumption.

### SUMMARY OF THE INVENTION

Embodiments of the present invention provide a level shifter capable of realizing a lower power-consumption circuit than the conventional level shifter by significantly reducing the short circuit current by means of a voltage boosting operation using a capacitor coupling effect. In addition, the level shifter uniformly maintains the rising and falling propagation delays of the output waveform by including a capacitor, a transistor for resetting the capacitor, and a transistor for initially charging the capacitor.

Embodiments of the present invention also provide a level shifter consisting of an initial charging part and n number of level shifter parts individually connected with the initial charging part, wherein the initial charging part resets the charging of the capacitor provided in each of the level shifter parts. Each of the level shifter parts realize a lower power-consumption circuit than conventional level shifters by significantly reducing the short circuit current by means of a voltage boosting operation using a capacitor coupling effect. In addition, the each of the level shifters uniformly maintain a rising propagation delay and a falling propagation delay of the output waveform.

A first embodiment of the present invention is achieved by providing a level shifter for a flat panel display device. The embodiment includes a first transistor connected with a first power supply and to which the gate and the drain are connected together. A capacitor is connected between the input voltage terminal and the first node, which is connected to the drain and to the gate of the first transistor. A second transistor is connected with the first node to reset the capacitor. The embodiment also includes a third transistor in which the gate is connected to the first node, and the source and the drain are connected between the second power supply and the output voltage terminal; and a fourth transistor in which the gate is connected to the input voltage terminal, and the source and the drain are connected between the ground voltage terminal and the output voltage terminal.

The second embodiment of the present invention is achieved by providing a level shifter for a flat panel display device including a first transistor connected to the ground voltage terminal or a third power supply, and with the gate and the drain connected together; a capacitor connected between the input voltage terminal and the first node, which is connected to the gate and the drain of the first transistor; a second transistor connected between the first node and the ground voltage or the third power supply to reset the capacitor; a third transistor in which the gate is connected to the first node, and the source and the drain are connected between a third power supply and the output voltage terminal; and a fourth transistor in which the gate is connected to the input voltage, and the source and the drain are connected between the first power supply and the output voltage terminal.

The third embodiment of the present invention is achieved by providing a level shifter for a flat panel display device consisting of an initial charging part and the n number of level shifter parts individually connected with the initial charging part, wherein the level shifter part includes a first transistor in which the signal output from the initial charging part is applied to the gate; a capacitor connected between the input voltage and the first node to which the drain of the first transistor is connected; a second transistor in which the gate is connected to the first node, the source is connected to the second power supply, and the drain is connected to the output terminal; and a third transistor in which the gate is connected to the input voltage, the source is connected to ground, and the drain is connected to the output terminal.

The fourth embodiment of the present invention is achieved by providing a level shifter for a flat panel display device consisting of an initial charging part including a level-up circuit part for receiving a reset signal (reset) and a reversed reset signal (resetb) to level up to a predetermined voltage; a buffer part for stabilizing the output voltage of the level-up circuit part; and the n number of level shifter parts individually connected with the initial charging part, wherein the level shifter part includes a first transistor in which the signal output from each of the initial charging parts is applied to the gate, and provided between a first node and a third power supply or a ground voltage; a capacitor connected between the first node and an input voltage terminal; a second transistor in which the gate is connected to the first node, the source is connected to the third power supply or ground, and the drain is connected to the output terminal; and a third transistor in which the gate is connected to the input voltage terminal, the source is connected to the first power supply, and the drain is connected to the output terminal.

### BRIEF DESCRIPTION OF THE DRAWINGS

FIG. 1A and FIG. 1B are circuit diagrams showing a configuration of the conventional level shifter.

FIG. 2 is a circuit diagram showing a level shifter according to the first embodiment of the present invention.

FIG. 3A and FIG. 3B are diagrams illustrating an operation of the level shifter circuit as shown in FIG. 2.

FIG. 4A and FIG. 4B are diagrams showing the operational characteristics of the level shifter circuit as shown in FIG. 2.

FIG. 5A, FIG. 5B, FIG. 5C, and FIG. 5D are circuit diagrams showing a level shifter according to the second embodiment of the present invention.

FIG. 6A and FIG. 6B are circuit diagrams showing a level shifter according to the third embodiment of the present invention.

FIG. 7A, FIG. 7B, and FIG. 7C are diagrams illustrating an operation of the level shifter circuit as shown in FIG. 6A.

FIG. 8A, FIG. 8B, and FIG. 8C are diagrams illustrating an operation of the level shifter circuit as shown in FIG. 6B.

FIG. 9A and FIG. 9B are circuit diagrams showing a level shifter according to the fourth embodiment of the present invention.

### DETAILED DESCRIPTION

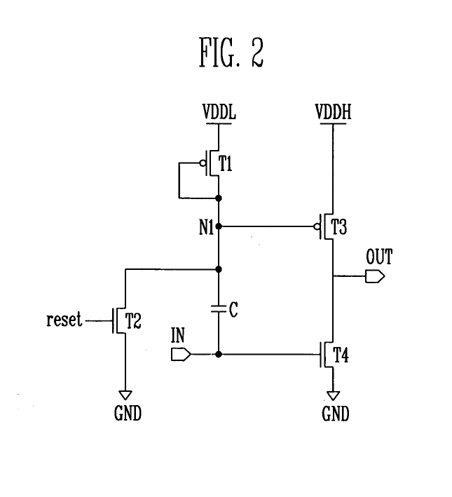

FIG. 2 is a circuit diagram showing a level up shifter according to the first embodiment of the present invention. The first power supply VDDL and the second power supply VDDH are the supply voltages of the level up shifter. IN is the input voltage and OUT is the output voltage of the level up shifter.

As shown in FIG. 2, a level up shifter according to an embodiment of the present invention includes a first transistor T1 with its gate connected to its drain in a diode connection and its source connected to a first power supply VDDL; a capacitor C connected between a first node N1 and an input voltage IN terminal; a second transistor T2 connected with the first node N1 to reset the capacitor C; a third transistor T3 in which the gate is connected to the first node N1, and the source and drain are connected between a second power supply VDDH and an output voltage OUT terminal; and a fourth transistor T4 in which the gate is connected to the input voltage IN terminal, and the source and drain are connected between a ground voltage GND terminal and the output voltage OUT terminal.

As shown in FIG. 2, the first transistor T1 is a diode-connected P-channel transistor, but the invention is not so limited, as the first transistor may be a diode-connected N-channel transistor or consist of diode-connected N-channel transistors.

The second transistor T2 is configured so that a reset pulse can be applied to the gate. The source of the second transistor T2 can be connected to a ground voltage GND and the drain can be connected to the first node N1. The second transistor T2 is turned on by the reset pulse applied to the gate, and therefore takes a role in resetting the capacitor C. Turning on the second transistor T2 transfers the ground voltage GND to the first node N1. The reset pulse is applied once for the operation of the level up shifter according to an embodiment of the present invention, therefore the capacitor is reset to a ground voltage by means of the operation.

Both the third transistor T3 and fourth transistor T4 are not turned on at the same time because they are configured in a different type. The third transistor T3 is a p-channel transistor and the fourth transistor T4 is an n-channel transistor. That is, the third transistor T3 operates as a pull-up transistor and the fourth transistor T4 operates as a pull-down transistor.

A level shifter circuit according to one embodiment of the present invention includes one capacitor; first and second transistors T1, T2 for initially resetting the capacitor so as to charge the capacitor to prevent a reverse current that may be generated by a capacitor coupling effect; and a third transistor T3 as the pull-up transistor for receiving a voltage, boosted by the capacitor coupling through the gate; and a fourth transistor T4 as the pull-down transistor for receiving an input voltage IN through the gate.

In this embodiment of the present invention the voltage swing ranges between the gates and the sources of the pull-up transistor and the pull-down transistor are divided from each other and realized independently, and therefore the voltage swing ranges between the gates and the sources of the pull-up transistor and the pull-down transistor may be reduced by half, which minimizes its power consumption.

The source of the third transistor T3 is connected to a second power supply VDDH and the drain is connected to the output voltage OUT terminal. The source of the fourth transistor T4 is connected to a ground voltage GND terminal and the drain is connected to the output voltage OUT terminal.

The second power supply VDDH is characterized in that it is greater than the first power supply VDDL used for charging the capacitor C.

In one exemplary embodiment, the second power supply VDDH is supplied at a level 2 times greater than the first power supply VDDL.

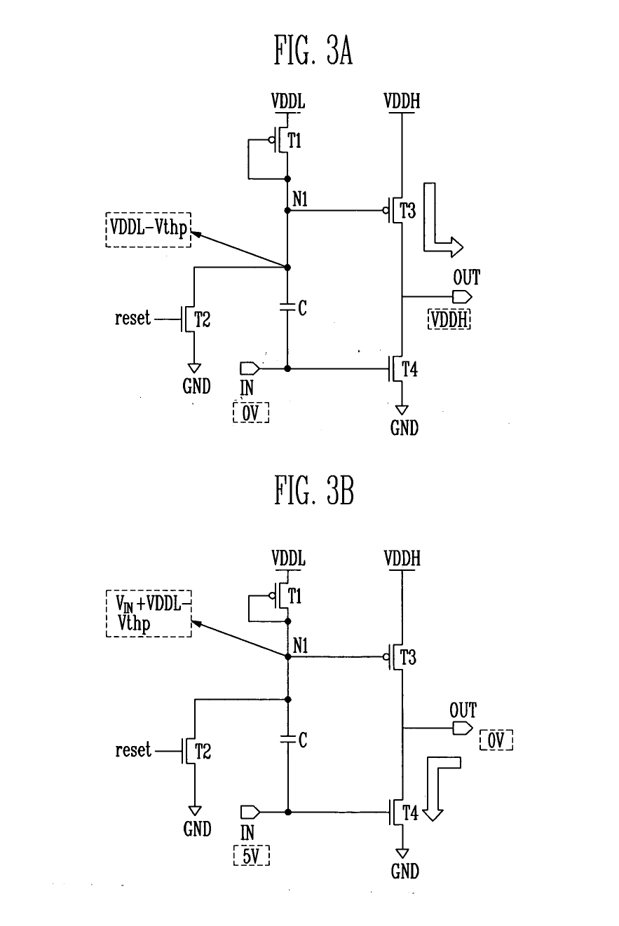

FIG. 3A and FIG. 3B are diagrams illustrating the operation of the level shifter circuit as shown in FIG. 2. For the description of the operation, the input voltage will range from 0 V to 5 V, the first power supply VDDL will be 5 V, the second power supply VDDH will be 10 V, and the output voltage will therefore range between 0 V and 10 V. Although the description assumes these values, the invention is not so limited.

In FIG. 3A, if the input signal IN is applied with a low level, namely 0 V, then the first node N1 returns to VDDL−Vth, namely 5 V−Vth, by the diode-connected first transistor T1 to charge 5 V−Vth across the capacitor C. Here, Vth represents the threshold voltage of the first transistor T1.

However, when the input signal IN is applied with an initial low level, namely 0 V, then the capacitor C is reset to the ground voltage GND by turning on the second transistor T2.

At this time, the drain of the diode-connected first transistor T1 becomes 5 V−Vth, and therefore 5 V−Vth is also applied to the gate, which is connected to the drain, and therefore the first transistor T1 is turned off.

The third transistor T3 is the pull-up transistor in which the gate connected to the first node N1 has a voltage difference of 5 V+Vth between the source and the gate, as the first node N1 is charged with 5 V−Vth, and therefore the third transistor T3 is turned on.

Meanwhile, the fourth transistor T4, which is the pull-down transistor, has a voltage difference of 0 V between the gate and the source, as the input voltage IN connected with the gate is set to 0 V, and the ground voltage GND applied to the source is set to 0 V, and therefore the fourth transistor T4 is turned off.

Accordingly, the output voltage OUT becomes 10 V by means of the second power supply VDDH, as it is connected to the source of the third transistor T3.

In FIG. 3B, if the input signal IN makes a transition from a low level (0 V) to a high level (5 V), then the voltage of the first node N1 is boosted to V_{IN}+VDDL−Vth, namely 10 V−Vth by the capacitor coupling effect. As a result, the first transistor T1 is turned off. Accordingly, the voltage of the first node N1 may be allowed to maintain 10 V−Vth by suppressing a reverse current that may be generated by the capacitor coupling effect.

With the first node N1 at 10 V−Vth, the third transistor T3 has a voltage difference of Vth between the source and the gate, therefore the third transistor T3 is turned off.

Meanwhile, the fourth transistor T4 has a voltage difference of 5 V between the gate and the source, as the input voltage IN connected with the gate is set to 5 V, and the ground voltage GND applied to the source is set to 0 V, and therefore the N-channel transistor-type fourth transistor T4 is turned on.

Accordingly, the output voltage OUT becomes 0 V due to the fourth transistor T4 turning on.

In this embodiment of the present invention the voltage swing ranges between the gates and the sources of the pull-up transistor T3 and the pull-down transistor T4 are divided from each other and realized independently, and therefore the voltage swing ranges between the gates and the sources of the pull-up transistor and the pull-down transistor may be reduced by half when compared to conventional level shifters, which minimizes its power consumption.

The short circuit current is very low, as one of the third and fourth transistors is turned on after the input voltage makes a structural transition. The rising and falling propagation delay may be set identically, as the output voltage terminal undergoes the same phases when its voltage is changed from 10 V to 0 V or from 0 V to 10 V.

The level shifter according to the present embodiment is characterized in that voltage swing ranges between the gates and the sources of the pull-up and pull-down transistors T3, T4 are divided from each other and realized independently, and therefore the voltage swing ranges between the gates and the sources of the pull-up and pull-down transistors may be reduced by half when compared to the conventional level shifters, which minimizes its power consumption.

In addition, the short circuit current is very low, as the third transistor T3 and the fourth transistor T4 are turned on after the input voltage IN makes a structural transition. The rising propagation delay and the falling propagation delay may be set to the identical extent because the output voltage OUT terminal undergoes the same phases when its voltage is changed from 10 V to 0 V or from 0 V to 10 V.

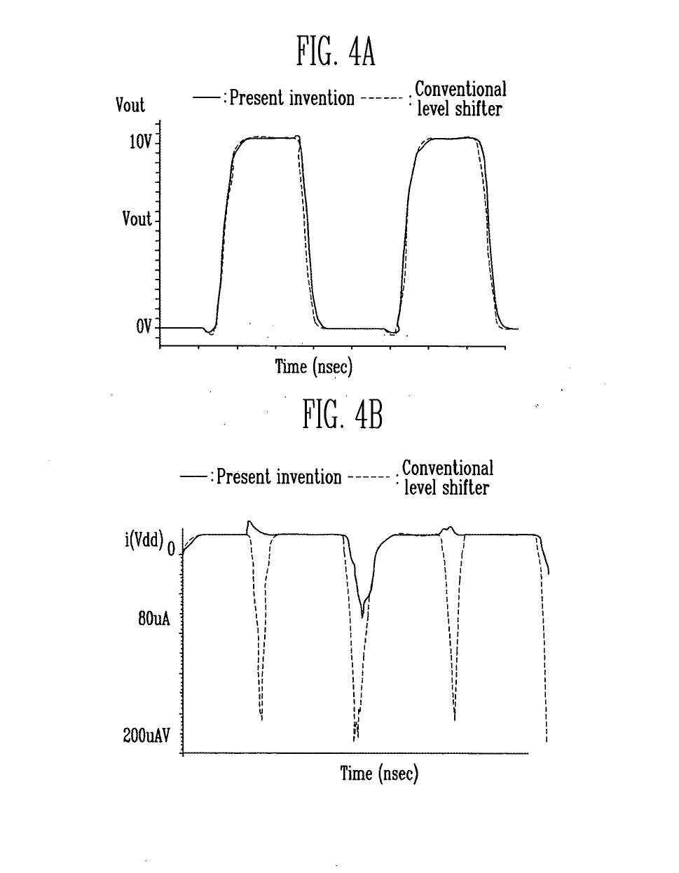

FIG. 4A and FIG. 4B are diagrams showing the operational characteristics of the level shifter circuit as shown in FIG. 2. FIG. 4A shows the output waveform of the level shifter circuit as shown in FIG. 2. FIG. 4B shows the current waveform supplied from the power source.

As shown in FIG. 4A, the output waveform of the level shifter according to one embodiment of the present invention exhibits a uniform rising propagation delay and a uniform falling propagation delay when compared to the output waveform of the conventional level shifter.

As shown in FIG. 4B, the output waveform of the level shifter according to one embodiment of the present invention has a low short circuit current in comparison to the conventional level shifter.

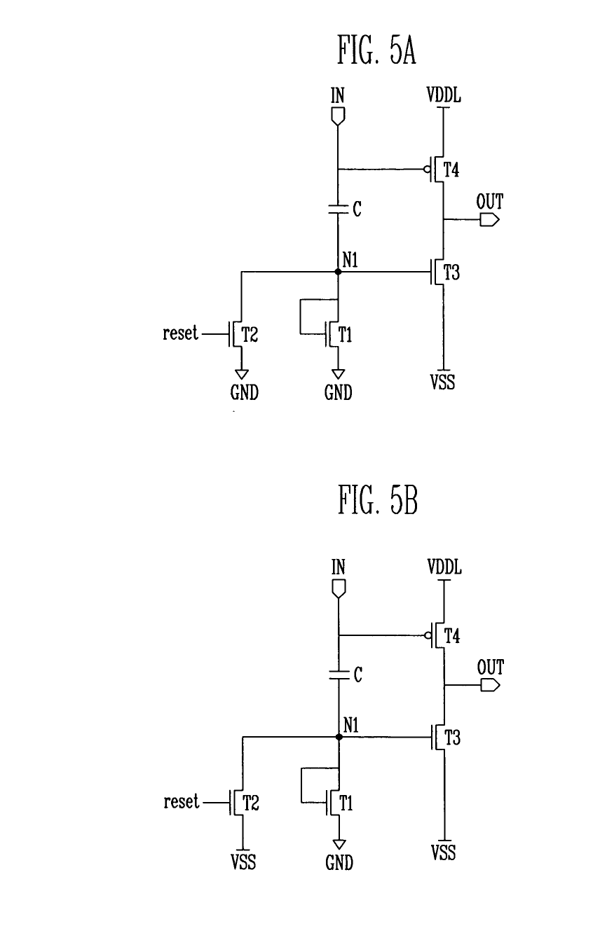

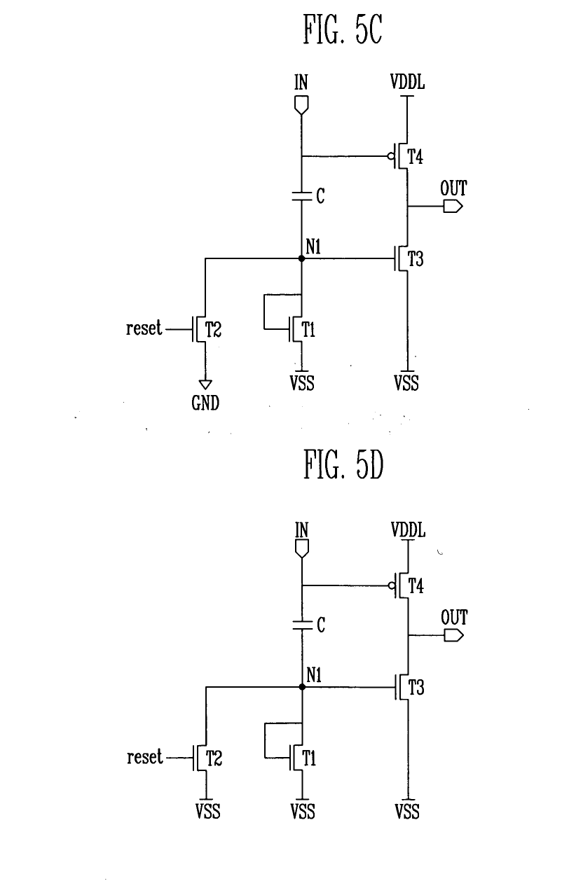

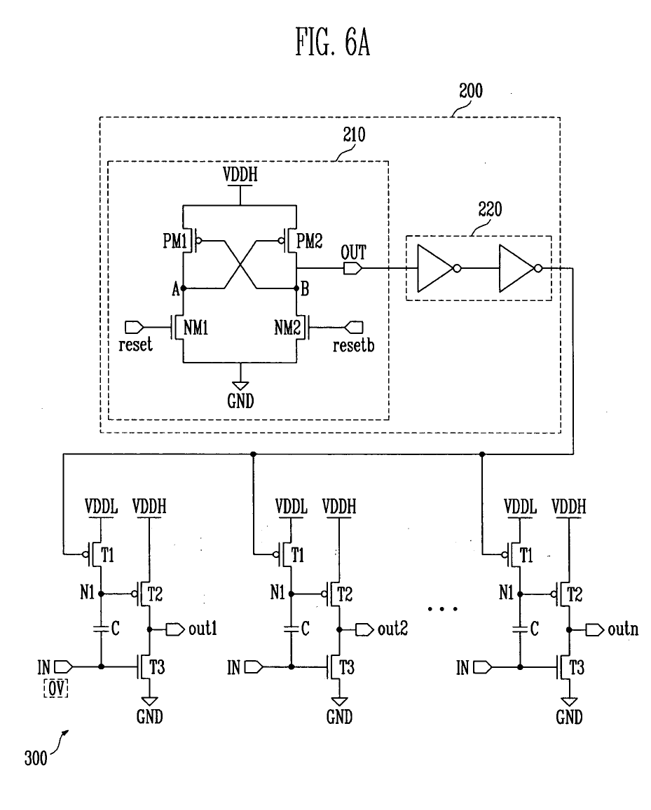

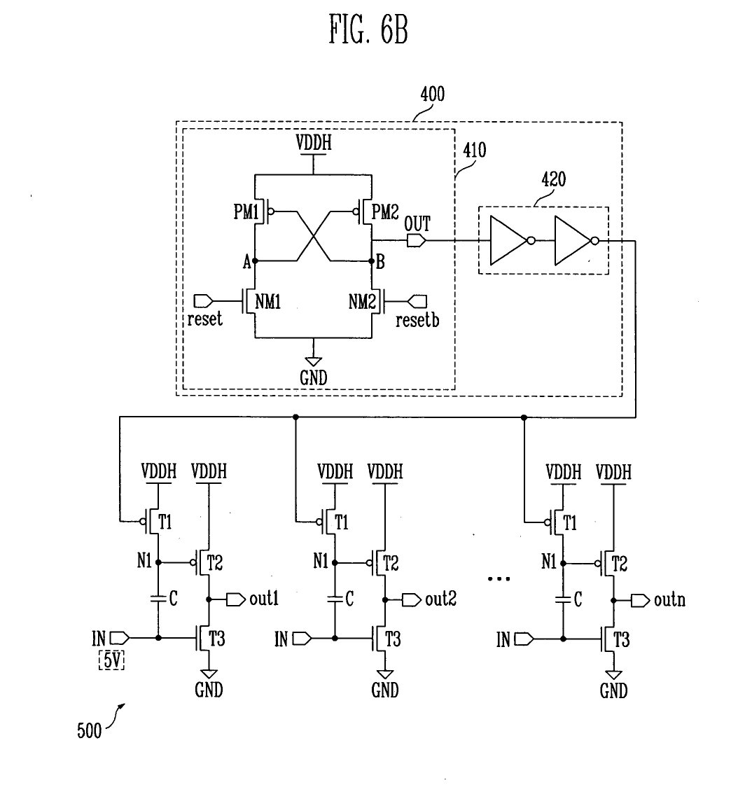

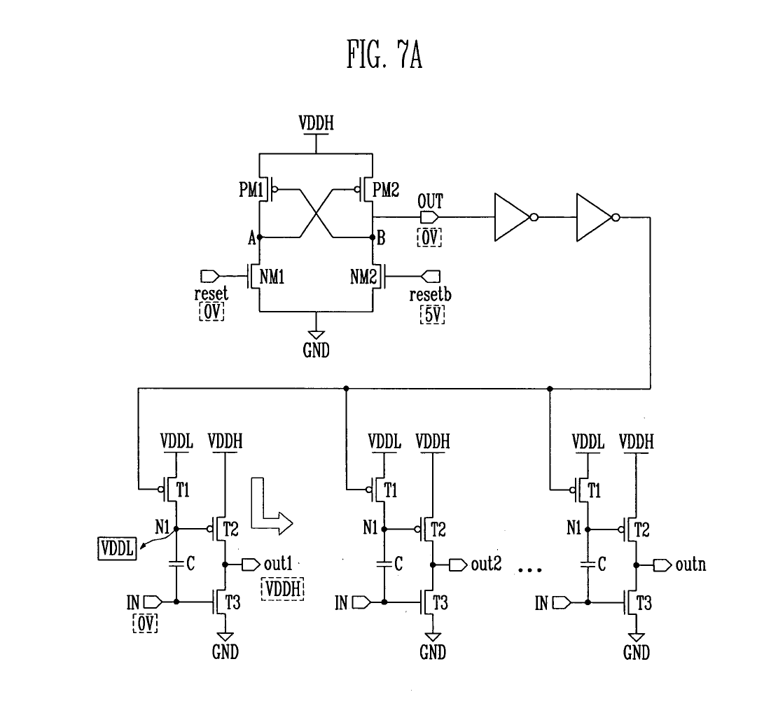

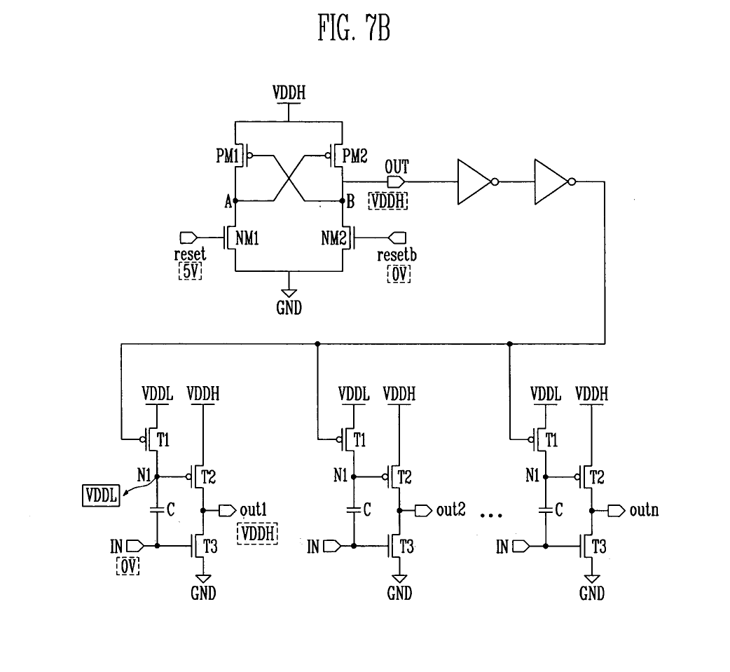

FIG. 5A to FIG. 5D are circuit diagrams showing a level down shifter according to the second embodiment of the present invention. The level down shifter differs from the level up shifter by the diode-connected transistor and the third power supply VSS, which has a negative voltage.

The first power supply VDDL and the third power supply VSS are supply voltages for the level down shifter. IN is the input voltage. OUT is the output voltage.

The level down shifter according to one embodiment of the present invention includes a diode-connected first transistor T1 with its source connected to ground GND or a third power supply VSS; a capacitor C connected between the first node N1 and the input voltage IN; a second transistor T2 with its source connected to ground GND or the third power supply VSS and its drain connected to the first node N1 to reset the capacitor C; a third transistor T3 in which the gate is connected to the first node N1, and the source and the drain are connected between the third power supply VSS and the output terminal OUT; and a fourth transistor T4 in which the gate is connected to the input terminal IN, and the source and the drain are connected between the first power supply VDDL and the output terminal OUT.

The level down shifters, as shown in FIG. 5A to FIG. 5D, are divided into embodiments with respect to whether the ground voltage GND or the third power supply VSS is connected to the sources of the first transistor T1 and the second transistor T2, and whether the input voltage IN is set to an initial low level or an initial high level.

The first transistor T1 is connected to the ground voltage GND or the third power supply VSS through the source, and is diode connected such that the gate and the drain are connected to each other, and the drain is connected to the first node N1.

The sources of the second transistor T2 and the first transistor T1 may be set to ground GND or the third power supply VSS in various configurations, as shown in FIG. 5A through FIG. 5D.

As shown in FIG. 5A to FIG. 5D, the first transistor T1 is a diode-connected N-channel transistor, but other embodiments may include diode-connected P-channel transistors.

The second transistor (T2) may be configured so that a reset pulse can be applied to the gate, the source can be connected to a ground voltage (GND) or a third power supply (VSS), and the drain can be connected to the first node (N1).

The second transistor T2 is turned on by the reset pulse applied to the gate, and therefore resets the capacitor C. When turned on, the second transistor T2 sets the first node N1 to ground GND.

The reset pulse is applied once for the operation of the level up shifter according to an embodiment of the present invention, and therefore the capacitor is reset to a ground voltage or third power supply VSS by means of the operation.

The third transistor T3 and the fourth transistor T4 are not turned on at the same time, as they are of a different type. The third transistor T3 includes N-channel transistors and the fourth transistor T4 includes P-channel transistors.

A level down shifter circuit according to each embodiment of the present invention includes one capacitor; first and second transistors for initially resetting the capacitor so as to charge the capacitor and prevent a reverse current that may be generated by a capacitor coupling effect; a third transistor T3 as the pull down transistor for receiving a voltage, boosted by the capacitor coupling, into an input signal through the gate; and a fourth transistor T4 as the pull up transistor for receiving an input voltage IN through the gate.

The source of the third transistor T3 is connected to a third power supply VSS, and the drain is connected to the output voltage OUT terminal; and the source of the fourth transistor T4 is connected to a first power supply VDDL, and the drain is connected to the output voltage OUT terminal.

The level down shifter operates under the same principles as in the level up shifter. For the description of the operation of this embodiment, the first power supply VDDL is 5 V, the third power supply VSS is −5 V, and the input voltage IN ranges from 0 V to 5 V. Although the description assumes these values, the invention is not so limited.

In FIG. 5A, a ground voltage GND is applied to sources of a first transistor T1 and a second transistor T2, respectively. If the input voltage IN is set to a high level, namely 5 V, and the first node N1 is reset to 0 V, then the output OUT of the level down shifter will be −5 V, as the third transistor T3 will turn on and pull down the voltage to the third power supply VSS.

On the other hand, if the input voltage IN makes a transition from a high level to a low level, then the first node returns to −5 V, and therefore the level down shifter is output with 5 V, as the fourth transistor T4 is turned on, which pulls up the output OUT to the first power supply VDDL voltage.

In FIG. 5B, the ground voltage GND and the third power supply VSS are applied to sources of the first transistor T1 and the second transistor T2, respectively, and the input voltage IN is input with an initial low level, namely 0 V.

In this case, if the input voltage IN is input with a low level as the first node is reset to −5 V, then the level down shifter is output with 5 V, as the fourth transistor turns on and pulls up the output OUT to the voltage of the first power supply VDDL.

On the other hand, if the input voltage IN makes a transition from a low level to a high level, then the first node N1 returns to 0 V, and therefore the level down shifter is output with the third power supply VSS, namely −5 V, as the third transistor T3 is turned on and pulls down the output OUT.

Subsequently, in the case of the embodiment as shown in FIG. 5C, the third power supply VSS and the ground voltage GND are applied to sources of the first transistor T1 and the second transistor T2, respectively, and the input voltage IN is input with an initial low level, namely 0 V.

In this case, if the input voltage IN is input with a low level as the first node is reset to −5 V+Vth (the threshold voltage of the T1), then the level down shifter is output with 5 V, which is the reversed input voltage INb, due to the fourth transistor T4 turning on.

If the input voltage IN makes a transition from a low level to a high level, then the first node returns to 0 V+Vth (the threshold voltage of the T1), and therefore the level down shifter is output with the third power supply VSS, namely −5 V, as the third transistor T3 is turned on.

Finally, in the case of the embodiment as shown in FIG. 5D, the third power supply VSS is applied to sources of the first transistor T1 and the second transistor T2, respectively. The input voltage IN is input with an initial low level, namely 0 V.

In this case, if the input voltage IN is input with a low level as the first node is reset to −5 V, then the level down shifter is output with 5 V, which is the first power supply VDDL, due to the fourth transistor T4 turning on.

If the input voltage IN makes a transition from a low level to a high level, then the first node returns to 0 V, and therefore the level down shifter is output with the third power supply VSS, namely −5 V, as the third transistor T3 is turned on.

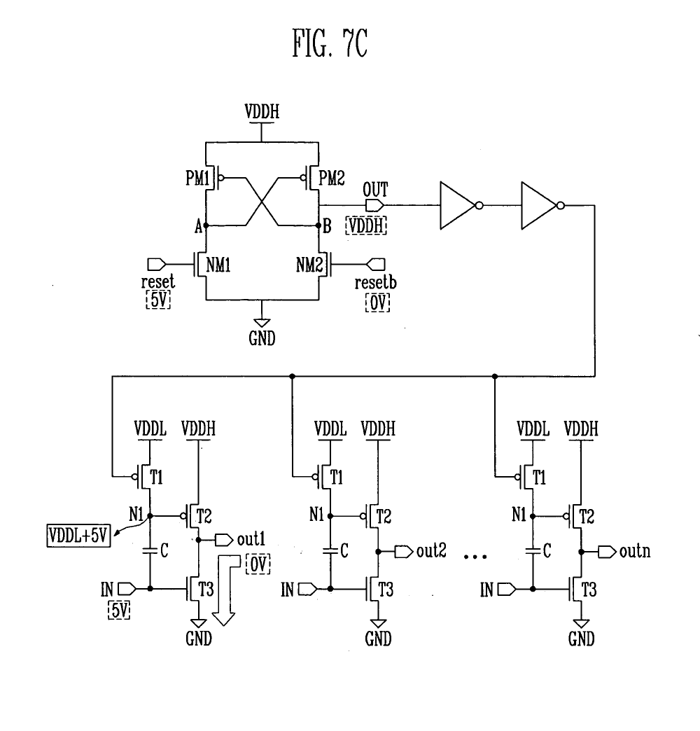

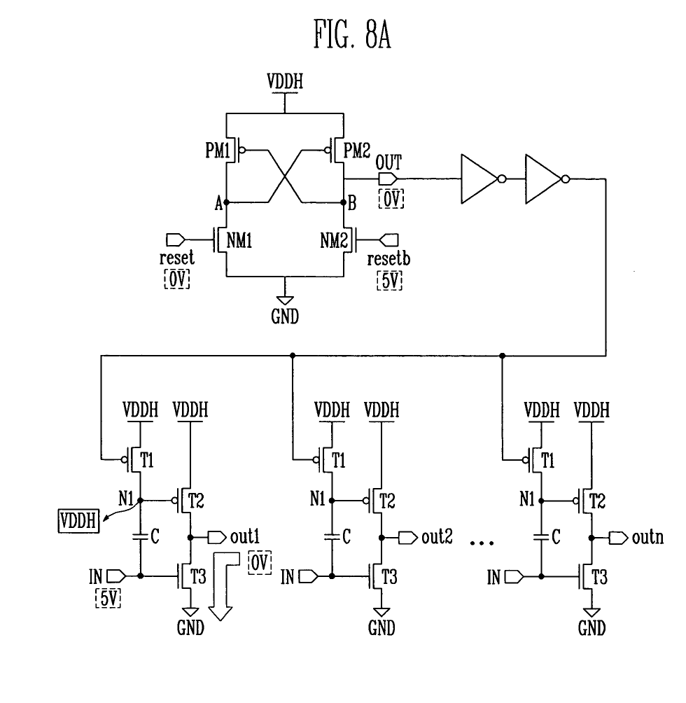

FIG. 6A and FIG. 6B are circuit diagrams showing a level shifter according to the third embodiment of the present invention.

The first power supply VDDL and the second power supply VDDH are supply voltages of the level shifter, IN is the input voltage of the level shifter, and out 1 through out n are the outputs.

The second power supply VDDH is a positive voltage greater than that of the first power supply VDDL. Preferably it has a voltage value 2 times greater than that of the first power supply VDDL.

In the description of the operation of this embodiment, the second power supply VDDH will be assumed to be 10 V and the first power supply VDDL 5 V, but the embodiment is not so limited to these voltage values.

Hereinafter, a configuration and an operation of the level shifter according to this embodiment of the present invention will be described in detail with reference to FIG. 2.

The level shifter according to the embodiment of the present invention includes an initial charging part 200 and the n number of level shifter parts 300 individually connected with the initial charging part 200, as shown in FIG. 6A.

The n number of the level shifter parts 300 is provided in order to supply the level-shifted voltage for the input voltage to each channel, and one initial charging part 200 is connected to each of the level shifter parts 300 in order to charge initially the capacitor C provided in each of the n number of the level shifter parts 300.

For this purpose, the initial charging part 200 resets the charging of the capacitor provided in each level shifter part. Each of the level shifter parts 300 realizes a low power-consumption circuit by significantly reducing the short circuit current by means of a voltage boosting operation using a capacitor coupling effect. And, each of the level shifter parts 300 takes a role in uniformly maintaining a rising propagation delay and a falling propagation delay of the output waveform.

The initial charging part 200 includes a buffer part 220 and a level-up circuit part 210 for receiving a reset signal (reset) and a reversed reset signal (resetb) to level up to a predetermined voltage.

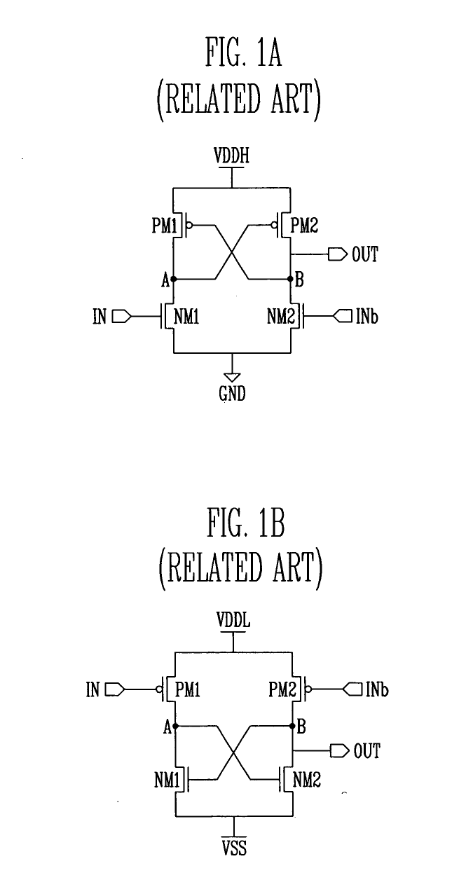

The level-up circuit part 210 may have the same structure as the conventional level shifter as shown above in FIG. 1, and therefore the level-up circuit part as shown in FIG. 6A and FIG. 6B includes first and second N-channel transistors NM1, NM2 for receiving a reset signal (reset) and a reversed reset signal (resetb); and a latch circuit for leveling up the input voltage. The latch circuit includes the first and second P-channel transistors PM1, PM2.

In NM1 and NM2, the gate is connected with the reset signal (reset) and the reversed reset signal (resetb), respectively, the source is connected with a ground voltage GND, and the drain is connected with the first and second nodes A, B, respectively, thereby being connected to the latch circuit. The second node B is connected with the output terminal OUT.

The gate and drain of PM1 and PM2 constituting the latch circuit are cross-linked between the first and second nodes, respectively, and the source is connected to the supply voltage VDDH of the level-up circuit part.

With respect to the level-up circuit part 210, if the reset signal ranges from 0 V to 5 V, and the output voltage OUT ranges from 0 V to 10 V, then the reversed reset signal (resetb) will be at a low level, namely 0 V, when the reset signal (reset) is at a high level, namely 5 V, and the reversed reset signal (resetb) will be at a high level (5 V) when the reset signal (reset) is at a low level (0 V).

If the reset is 5 V, then NM1 to which the reset is applied is turned on, and NM2 to which the resetb is applied is turned off. Accordingly, PM2 is turned as a result of NM1 turning on, and the output voltage OUT is leveled up to 10 V by the supply voltage VDDH.

Meanwhile, if the reset is 0 V, then NM2 to which the resetb is applied is turned on, and NM1 to which the reset is applied is turned off, therefore the output voltage OUT returns to 0 V.

As described above, the output voltage of the level-up circuit part is supplied to the n number of level shifter parts through the buffer part 220. The buffer part may, for example, have a structure in which two inverters are connected in series, as shown in FIG. 6A and FIG. 6B.

The level shifter part 300 includes a first transistor T1 in which the signal output from each of the initial charging parts is applied to the gates, the source is connected to the first power supply VDDL, and the drain is connected to the first node N1; a capacitor C connected between the first node N1 and the input voltage IN terminal; a second transistor T2 in which the gate is connected to the first node N1, the source is connected to the second power supply VDDH, and the drain is connected to the output voltage OUT terminal; and a third transistor T3 in which the gate is connected to the input voltage IN terminal, the source is connected to ground GND, and the drain is connected to the output voltage OUT terminal.

As shown in FIG. 6B, the level shifter includes an initial charging part 400 and n number of level shifter parts 500 individually connected with the initial charging parts 400. One initial charging part 400 is connected to each of the level shifter parts 500 in order to charge initially the capacitor C provided in each of the n number of the level shifter parts 500. Accordingly, the configuration and operation of the initial charging part 400 is identical to the embodiment as shown above in FIG. 6A.

The configuration of the level shifter part 500 is identical to that of the embodiment as shown in FIG. 6A except the second power supply VDDH is connected to the sources of the first transistors T1 and the input voltage IN is input with an initial high level rather than an initial low level.

Both the second transistor T2 and the third transistor T3 are not turned on at the same time because they are of a different type in each embodiment of FIG. 6A and FIG. 6B. That is, the second transistor T2 is a P-channel transistor and operates as a pull-up transistor and the third transistor T3 is an N-channel transistor and operates as a pull-down transistor.

As described above, the level shifter part according to the embodiment of the present invention includes one capacitor; a first transistor for initially resetting the capacitor so as to charge the capacitor and prevent a reverse current that may be generated by a capacitor coupling effect; a second transistor T2 as the pull-up transistor for receiving a voltage, boosted by the capacitor coupling, into an input signal through the gate; and a third transistor T3 as the pull-down transistor configured in an opposite type to the second transistor T2.

In this embodiment, the voltage swing ranges between the gates and the sources of the pull-up transistor and the pull-down transistor are divided from each other and realized independently, and therefore the voltage swing ranges between the gates and the sources of the pull-up transistor and the pull-down transistor may be reduced by half when compared to the conventional level shifters, which minimizes its power consumption.

The source of the second transistor T2 is connected to a second power supply VDDH and the drain is connected to the output voltage (out 1˜out n) terminals. The source of the third transistor T3 is connected to the ground voltage GND terminal and the drain is connected to the output voltage (out 1˜out n) terminals.

The second power supply VDDH is characterized in that it is greater than the first power supply VDDL used for charging the capacitor C, and preferably has a positive voltage value 2 times greater than the first power supply VDDL.

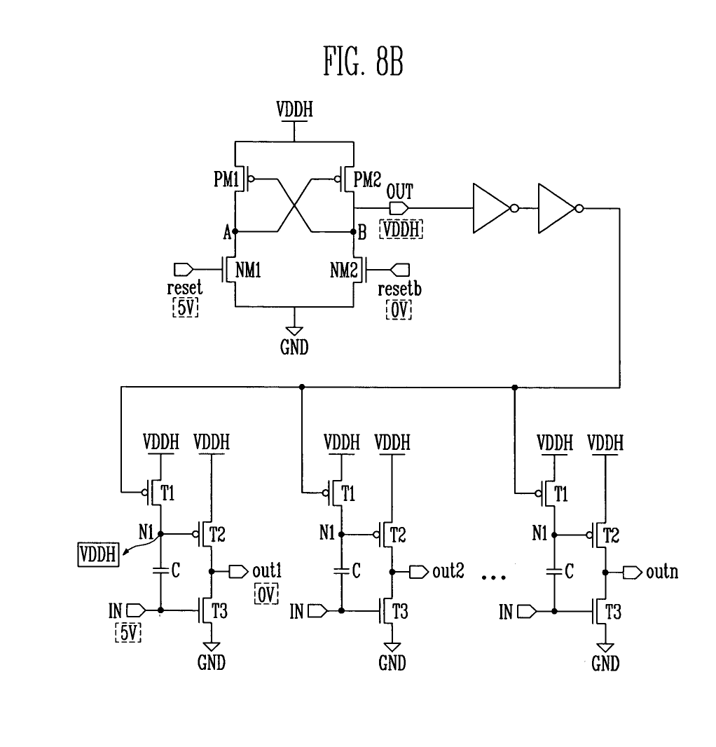

FIG. 7A to FIG. 7C are diagrams illustrating an operation of the level shifter circuit as shown in FIG. 6A.

The description of the operation will assume that the input voltage ranges from 0 V to 5 V, the output voltage OUT ranges from 0 V to 10 V, the first power supply VDDL is 5 V, the second power supply VDDH is 10 V, and the reset signal (reset) ranges from 0V to 5 V. Although the description assumes these values, the invention is not so limited.

If the input signal IN is applied with an initial low level, namely 0 V, then the reset signal (reset) of the level-up circuit part provided in the initial charging part is also supplied with a low level (0 V).

As a result, the initial charging part outputs the low level, namely 0 V, and then supplies the low level to the gate of the first transistor T1, provided in the level shifter part, through the buffer part, and the first transistor T1 is turned on by the signal because the first transistor T1 is a P-channel transistor.

Accordingly, the first power supply VDDL, namely 5 V is applied to the first node N1 and the capacitor C is initially charged with a voltage of 5 V.

Accordingly, the second transistor T2, as the pull-up transistor in which the gate is connected to the first node N1, has a voltage difference of VDDH-VDDL, namely 5 V, between the source and the gate, and therefore the second transistor T2 is turned on because the second transistor T2 is realized as a P-channel transistor as shown in FIG. 7A.

Meanwhile, the voltage difference between the gate and the source in the third transistor T3 is 0 V because the input voltage IN connected to the gate is 0 V, and a ground voltage GND applied to the source is 0 V, and therefore the third transistor T3 is turned off.

Accordingly, the output voltage OUT terminal becomes 10 V by means of the second power supply VDDH, as the second transistor T2 is on.

The reset signal (reset) of the level-up circuit part provided in the initial charging part as shown in FIG. 7B is set to a high level (5 V) after a voltage of 5 V is applied to the first node N1 and the capacitor C is charged with a voltage of 5 V. Therefore the initial charging part outputs a voltage of VDDH, namely 10 V, which supplies the voltage of 10 V to the gate of the first transistor T1 provided in the level shifter part. As a result, the first transistor T1 is turned off.

As the first transistor T1 is turned off, the first node N1 floats, and the capacitor C is maintained with the initially charged 5 V, and the output voltage is also maintained with 10 V, as shown above in FIG. 7A.

That is, according to the present invention, the capacitor is not affected by the threshold voltage of the first transistor T1 and the first power supply VDDL may be maintained intact.

When the input signal IN is set to an initial low level, the reset signal (reset) is changed from a low level (0 V) to a high level (5 V), which turns off the first transistor T1. The charge of 5 V in the capacitor is maintained because the first node is floating.

In FIG. 7C, if the input signal IN is changed from a low level (0 V) to a high level (5 V), then the voltage of the first node N1 is boosted to IN (5 V)+VDDL (10 V) by the capacitor coupling effect.

The first transistor T1 is maintained turned-off, and therefore the voltage of the first node N1 may be maintained with 10 V because the reverse current which may be generated by the capacitor coupling effect is suppressed.

Accordingly, the second transistor T2 has a voltage difference of 0 V between the source and the gate, and therefore the second transistor T2 is turned off.

Meanwhile, the voltage difference between the gate and the source is 5 V in the third transistor T3, therefore the N-channel third transistor T3 is turned on.

The output voltage then becomes 0 V as a result of the third transistor T3 turning on.

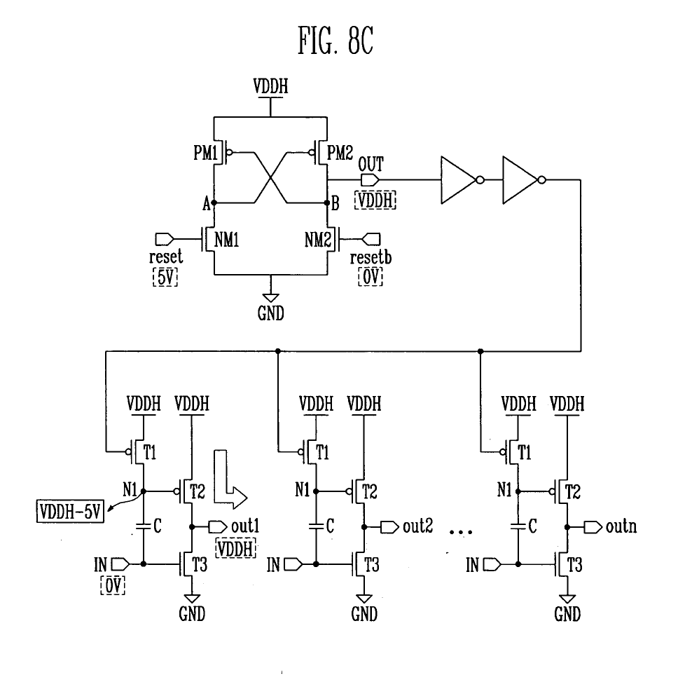

FIG. 8A to FIG. 8C are diagrams illustrating the operation of the level shifter circuit as shown in FIG. 6B. For the description of the operation, it is assumed that the input voltage IN ranges from 0 V to 5 V, the output voltage OUT ranges from 0 V to 10 V, the second power supply VDDH is 10 V, and the reset signal ranges from 0 V to 5 V. Although the description assumes these values, the invention is not so limited.

In comparison to the embodiment as shown in FIG. 6A, the first power supply VDDL is not supplied in FIG. 8A to FIG. 8C, therefore there is an advantage in that the second power supply VDDH may be freely supplied.

In FIG. 8A, the reset signal (reset) of the level-up circuit part provided in the initial charging part is supplied with a low level (0 V) if the input signal IN is applied with an initial high level, namely 5 V.

As a result, the initial charging part outputs the low level, namely 0 V, and then supplies the low level to the gate of the first transistor T1, provided in the level shifter part, through the buffer part, and the first transistor T1 is turned on by the signal, as the first transistor T1 is the P-channel transistor.

Therefore, the second power supply VDDH, namely 10 V is applied to the first node N1, and the capacitor C is initially charged with a voltage of VDDH−IN. With VDDH set to 10 V and IN to 5 V, this results with an initial charge across the capacitor of 5 V.

Accordingly, the second transistor T2 has a voltage difference of VDDH-VDDH, namely 0 V, between the source and the gate, and therefore the second transistor T2 is turned off.

The third transistor T3 has a voltage difference of 5 V between the gate and the source and therefore the third transistor T3 is turned on.

Accordingly, the output voltage OUT terminal becomes 0 V as a result of the third transistor T3 turning on.

In FIG. 8B, the reset signal (reset) of the level-up circuit part provided in the initial charging part is changed into a high level (5 V) after a voltage of 10 V is applied to the first node N1 and the capacitor C is charged with a voltage of 5 V. Therefore the initial charging part outputs a voltage of VDDH, namely 10 V, to supply the voltage of 10 V to the gate of the first transistor T1 provided in the level shifter part. As a result, the first transistor T1 is turned off.

As the first transistor T1 is turned off, the first node floats, and the capacitor C is maintained with the initially charged 5 V. The output voltage is also maintained with 10 V, as described above in FIG. 8A.

According to the present invention, the capacitor is not affected by the threshold voltage of the first transistor T1 and the difference between the first power supply VDDL and the input voltage may be maintained intact.

When the input signal IN is set to an initial low level, the reset signal (reset) is changed from a low level (0 V) to a high level (5 V), and then supplied to the level-up circuit part provided in the reset charging part as shown in FIG. 8A and FIG. 8B, and therefore the first transistor T1 is turned off. The charge of 5 V in the capacitor is maintained because the first node is floating.

In FIG. 8C, if the input signal IN is changed from a high level (5 V) to a low level (0 V), the voltage of the first node N1 is changed into VDDH −5 V, namely 5 V, so as to maintain the voltage value stored in the capacitor by means of the capacitor coupling effect.

Accordingly, the second transistor T2 has a voltage difference of VDDH −5 V, namely 5 V, between the source and the gate, and therefore the second transistor T2 is turned on.

The third transistor T3 has a voltage difference of 0 V between the gate and the source because the input voltage IN connected to the gate is 0 V, and the ground voltage GND applied to the source is 0 V, and therefore the third transistor T3 is turned off.

Accordingly, the output voltage becomes VDDH, namely 10 V, as a result of the second transistor T2 turning on.

In this embodiment of the present invention the voltage swing ranges between the gates and the sources of the pull-up transistor and the pull-down transistor are divided from each other and realized independently, and therefore the voltage swing ranges between the gates and the sources of the pull-up transistor and the pull-down transistor may be reduced by half, which minimizes its power consumption.

In addition, the short circuit current is very low, as the third transistor T3 and the fourth transistor T4 are turned on after the input voltage IN makes a structural transition. The rising propagation delay and the falling propagation delay may be set to the identical extent because the output voltage OUT terminal undergoes the same phases when its voltage is changed from 10 V to 0 V or from 0 V to 10 V.

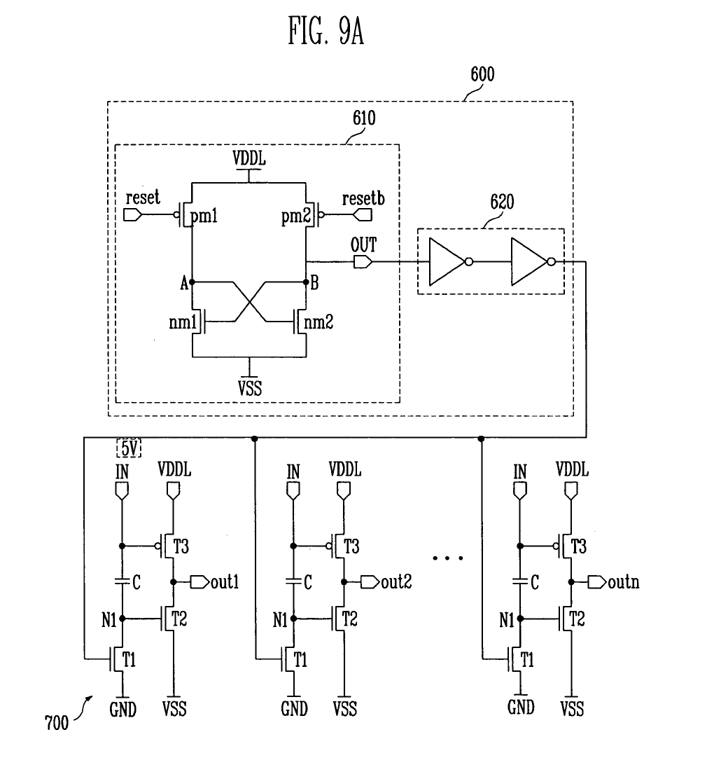

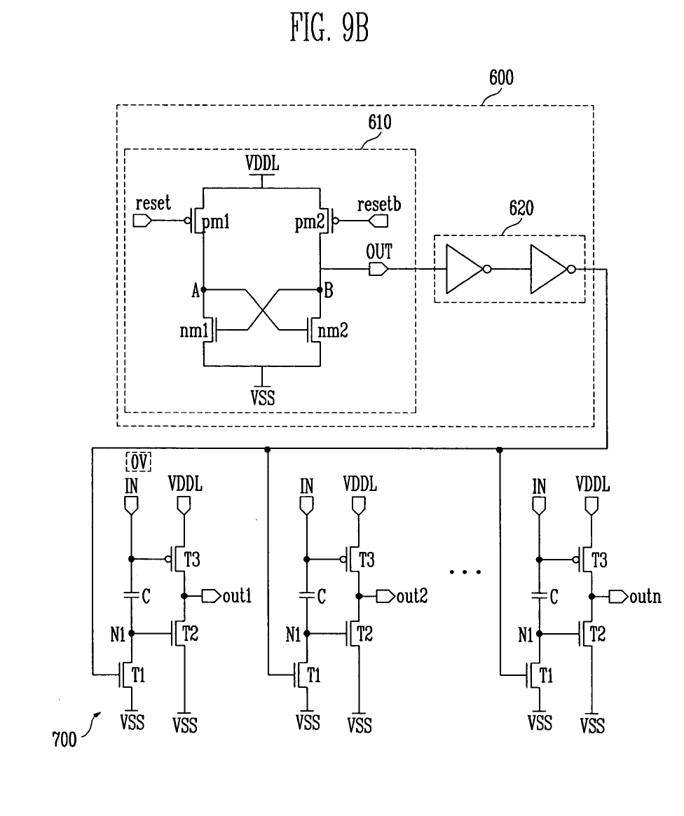

FIG. 9A and FIG. 9B are circuit diagrams showing a level shifter according to the fourth embodiment of the present invention. These are circuit diagrams of a level down shifter. The third power supply VSS has a negative voltage level.

The first power supply VDDL and the third power supply VSS are the supply voltages of the level down shifter. IN is the input voltage of the level down shifter. OUT is the output voltage.

The level down shifter according to the embodiment of the present invention includes an initial charging part 600 and the n number of level shifter parts 700 individually connected with the initial charging part 600.

The initial charging part 600 includes a buffer part 620 and a level down circuit part 610 for receiving a reset signal (reset) and a reversed reset signal (resetb) to level down to a predetermined voltage.

The level down circuit part 610 includes first and second P-channel transistors pm1, pm2 for receiving a reset signal (reset) and a reversed reset signal (resetb); and a latch circuit for leveling down the input voltage. The latch circuit includes first and second N-channel transistors nm1, nm2.

In pm1 and pm2, the gate is connected with the reset signal (reset) and the reversed reset signal (resetb), respectively, the source is connected with the first voltage VDDL, and the drain is connected with the first and second nodes A, B, respectively, thereby being connected to the latch circuit. The second node B is connected to the output voltage OUT terminal.

The gate and drain of nm1 and nm2 constituting the latch circuit are cross-linked between the first and second nodes, respectively, and the source is connected to the supply voltage, the third power supply VSS, of the level down circuit part.

For this configuration, the input voltage IN terminal may range from 0 V to 5 V and the output voltage may range from 0 V to 10 V, although the embodiment is not so limited to these values.

An output voltage of the level down circuit part is supplied to the n number of level shifter parts through the buffer part 620. The buffer part may have a structure in which two inverters are connected in series, as shown in FIG. 9A and FIG. 9B.

The level shifter part 700 includes a first transistor T1 in which the signal output from each of the initial charging parts is applied to the gate. The source of the first transistor T1 is connected to the third power supply VSS or the ground voltage GND and the drain is connect to the first node N1. The level shifter part 700 also includes a capacitor C connected between the first node N1 and the input voltage IN terminal; a second transistor T2 in which the gate is connected to the first node N1, the source is connect to the third power supply VSS and the drain is connected to the output voltage OUT terminal; and a third transistor T3 in which the gate is connected to the input voltage IN terminal, the source is connected to the first power supply VDDL and the drain is connected to the output voltage OUT terminal.

In FIG. 9A, the ground voltage GND is input into the source of the first transistor T1 and the input voltage IN is set with an initial high level (5 V). In FIG. 9B, the third power supply VSS is input into the source of the first transistor T1 and the input voltage IN is input with an initial low level (0 V).

The level down shifter operates under the same principles as the level up shifters in FIG. 6A, FIG. 6B, FIG. 7A through FIG. 7C, and FIG. 8A through FIG. 8C, therefore its detailed description is omitted.

As described above, the level shifter part of the invention realizes a lower power-consumption circuit by significantly reducing the short circuit current by means of a voltage boosting operation using a capacitor coupling effect. In addition, it uniformly maintains a rising propagation delay and a falling propagation delay of the output waveform.

Although exemplary embodiments of the present invention have been shown and described, it would be appreciated by those skilled in the art that changes might be made in the embodiments without departing from the principles and spirit of the invention, the scope of which is defined in the claims and their equivalents.

What is claimed is:

1. A level shifter comprising:
a first transistor having a first transistor gate, a first transistor source, and a first transistor drain, the first transistor source being connected to a first power supply, and the first transistor gate being connected to the first transistor drain;
a capacitor connected between an input voltage terminal and a first node with the first node connected to the first transistor gate and the first transistor drain;
a second transistor connected with the first node to reset the capacitor;
a third transistor having a third transistor gate, a third transistor source, and a third transistor drain, the third transistor gate being connected to the first node, and the third transistor source and the third transistor drain being connected between a second power supply and an output voltage terminal; and
a fourth transistor having a fourth transistor gate, a fourth transistor source, and a fourth transistor drain, the fourth transistor gate being connected to the input voltage terminal, and the fourth transistor source and the fourth transistor drain being connected between a ground voltage terminal and the output voltage terminal.

2. The level shifter according to claim 1, wherein the first transistor is a diode-connected P-channel transistor or a diode-connected N-channel transistor.

3. The level shifter according to claim 1, wherein the second transistor has a second transistor gate, a second transistor source, and a second transistor drain, the second transistor gate being connected to a reset pulse, the second transistor source being connected with the ground voltage terminal, and the second transistor drain being connected to the first node.

4. The level shifter according to claim 1, wherein the third transistor is a P-channel transistor and the fourth transistor is an N-channel transistor, or wherein the third transistor is an N-channel transistor and the fourth transistor is a P-channel transistor.

5. The level shifter according to claim 4, wherein the third transistor source is connected to the second power supply, the third transistor drain is connected to the output voltage terminal, the fourth transistor source is connected to the ground voltage terminal, and the fourth transistor drain is connected to the output voltage terminal.

6. The level shifter according to claim 1, wherein the second power supply has a voltage value twice that of the first power supply.

7. A level shifter comprising:
a first transistor having a first transistor source, a first transistor gate, and a first transistor drain, the first transistor gate being connected to a ground voltage terminal or to a third power supply, and the first transistor gate being connected to the first transistor drain;
a capacitor connected between an input voltage terminal and a first node with the first node connected to the first transistor gate and the first transistor drain;
a second transistor connected between the first node and the ground voltage terminal or the third power supply to reset the capacitor;
a third transistor having a third transistor gate, a third transistor source, and a third transistor source, the third transistor gate being connected to the first node, and the third transistor source and the third transistor drain being connected between the third power supply and an output voltage terminal; and
a fourth transistor having a fourth transistor gate, a fourth transistor source, and a fourth transistor drain, the fourth transistor gate being connected to the input voltage terminal, and the fourth transistor source and the fourth transistor drain being connected between a first power supply and the output voltage terminal.

8. The level shifter according to claim 7, wherein the first transistor is a diode-connected N-channel transistor or a diode-connected P-channel transistor.

9. The level shifter according to claim 7, wherein the second transistor has a second transistor gate, a second transistor source, and a second transistor drain, the second transistor gate being connected to a reset pulse, the second transistor source being connected with the ground voltage terminal or the third power supply, and the second transistor drain being connected to the first node.

10. The level shifter according to claim 7, wherein the third transistor is a P-channel transistor and the fourth transistor is an N-channel transistor, or wherein the third transistor is an N-channel transistor and the fourth transistor is a P-channel transistor.

11. The level shifter according to claim 10, wherein the third transistor source is connected to the third power supply, the third transistor drain is connected to the output voltage terminal, the fourth transistor source is connected to the first power supply, and the fourth transistor drain is connected to the output voltage terminal.

12. The level shifter according to claim 7, wherein the first power supply has a positive voltage value and the third power supply has a negative voltage value.

13. A level shifter comprising a charging part and a plurality of level shifter parts, each level shifter part being individually connected with the charging part, the charging part having a charging part signal output, wherein each level shifter part comprises:
a first transistor having a first transistor gate, a first transistor source, and a first transistor drain, the first transistor gate being connected to the charging part signal output;
a capacitor connected between an input voltage terminal and a first node with the first node connected to the first transistor drain;
a second transistor having a second transistor gate, a second transistor source, and a second transistor drain, the second transistor gate being connected to the first node, the second transistor source being connected to a second power supply, and the second transistor drain being connected to an output voltage terminal;
and a third transistor having a third transistor gate, a third transistor source, and a third transistor drain, the third transistor gate being connected to the input voltage terminal, the third transistor source being connected to a ground voltage terminal, and the third transistor drain being connected to the output voltage terminal.

14. The level shifter according to claim 13, wherein the first transistor source is connected with a first power supply and the first transistor drain is connected with the first node.

15. The level shifter according to claim 14, wherein the first power supply has a positive voltage less than that of the second power supply.

16. The level shifter according to claim 13, wherein the input voltage terminal is set to an initial low level.

17. The level shifter according to claim 13, wherein the first transistor source is connected with the second power supply and the first transistor drain is connected with the first node.

18. The level shifter according to claim 17, wherein the input voltage terminal is set to an initial high level.

19. The level shifter according to claim 13, wherein the second transistor is a P-channel transistor and the third transistor is an N-channel transistor, or wherein the second transistor is an N-channel transistor and the third transistor is a P-channel transistor.

20. The level shifter according to claim 13, wherein the charging part comprises a level-up circuit part that receives a reset signal and a reversed reset signal and that levels up to a predetermined voltage; and a buffer part that is connected between the level-up circuit part and a plurality of level-up shifters.

21. The level shifter according to claim 18, comprising:
the level shifter part, wherein the level shifter part includes a first N-channel transistor and a second N-channel transistor for receiving a reset signal and a reversed reset signal; and
a latch circuit having a first P-channel transistor and a second P-channel transistor.

22. A level shifter comprising:
a charging part having a level-up circuit part that receives a reset signal and a reversed reset signal and that levels up to a predetermined voltage, the charging part having a charging part output, and a buffer part for stabilizing the output voltage of the level-up circuit part;
a plurality of level shifter parts, each level shifter part being individually connected with the charging part,
wherein each level shifter part includes:
a first transistor having a first transistor gate, a first transistor source, and a first transistor drain, the first transistor gate being connected to the charging part output, the first transistor source being connected to a third power supply or a ground voltage terminal, and the first transistor drain being connected to a first node;
a capacitor connected between the first node and an input voltage terminal;
a second transistor having a second transistor gate, a second transistor source, and a second transistor drain, the second transistor gate being connected to the first node, the second transistor source being connected to the third power supply, and the second transistor drain being connected to an output voltage terminal; and
a third transistor having a third transistor gate, a third transistor source, and a third transistor drain, the third transistor gate being connected to the input voltage terminal, the third transistor source being connected to a first power supply, and the third transistor drain being connected to the output voltage terminal.

23. The level shifter according to claim 22, wherein the input voltage terminal is set to an initial high level if the ground voltage terminal is connected to the first transistor source.

24. The level shifter according to claim 22, wherein the input voltage is set to an initial low level if the third power supply is connected to the first transistor source.
